(19) United States
(12) Patent Application Publication
(10) Pub. No.: US 2012/0175726 A1
(43) Pub. Date: Jul. 12, 2012

(54) SEMICONDUCTOR DEVICE

(76) Inventor: Jin Kashiwagi, Kawasaki-shi (JP)

(21) Appl. No.: 13/281,705

(22) Filed: Oct. 26, 2011

(30) Foreign Application Priority Data
Jan. 6, 2011 (JP) 2011-001286

(51) Int. Cl. H01L 27/04

(52) U.S. Cl. 257/506; 257/E27.01

(57) ABSTRACT

According to one embodiment, a semiconductor device comprises a circuit portion, wells, and dummy wells. A circuit portion is formed on an upper surface of a semiconductor substrate of a first conductivity type. The wells are of a second conductivity type different from the first conductivity type. Each of wells is formed in the semiconductor substrate on an upper surface side, constitutes the circuit portion, and functions as an element. The dummy wells are of the second conductivity type. Each of the dummy wells is formed in the semiconductor substrate on the upper surface side, does not constitute the circuit portion, and does not function as an element.

### CROSS-REFERENCE TO RELATED APPLICATIONS

This application is based upon and claims the benefit of priority from prior Japanese Patent Application No. 2011-001286, filed Jan. 6, 2011, the entire contents of which are incorporated herein by reference.

### FIELD

Embodiments described herein relate generally to a semiconductor device.

### BACKGROUND

In a semiconductor device including, on the surface of a semiconductor (Si) substrate, a circuit portion formed from multilayered interconnections, the lower interconnections and the like are sometimes corrected after completion. As a method for this, backside FIB processing has been proposed which corrects interconnections and the like by irradiating a semiconductor substrate with a focused ion beam (FIB) from the lower surface. With this backside FIB processing, forming of pad for signal acquisition or reconnection of interconnections is performed in the circuit portion.

### BRIEF DESCRIPTION OF THE DRAWINGS

FIG. 1 is a schematic view showing the an FIB processing apparatus according to each embodiment;

FIG. 2 is a flowchart of backside FIB processing to be performed for the semiconductor device according to each embodiment;

FIG. 3 is a sectional view showing a midway process of the backside FIB processing to be performed for the semiconductor device according to each embodiment;

FIG. 4 is a sectional view showing a midway process of the backside FIB processing to be performed for the semiconductor device according to each embodiment following FIG. 3;

FIG. 5 is a sectional view showing a midway process of the backside FIB processing to be performed for the semiconductor device according to each embodiment following FIG. 4;

FIG. 6 is a sectional view showing a semiconductor device according to the first embodiment;

FIG. 7 is a plan view showing an example of the semiconductor device according to the first embodiment;

FIG. 8 is a plan view showing another example of the semiconductor device according to the first embodiment;

FIG. 9 is a plan view showing an example of a semiconductor device according to the second embodiment;

FIG. 10 is a plan view showing another example of the semiconductor device according to the second embodiment;

FIG. 11 is a sectional view showing a semiconductor device according to the third embodiment;

FIG. 12 is a plan view showing the semiconductor device according to the third embodiment;

FIG. 13 is a plan view showing a semiconductor device according to the fourth embodiment; and

FIG. 14 is a sectional view showing a comparative example of the semiconductor device related to the fourth embodiment.

### DETAILED DESCRIPTION

In general, according to one embodiment, a semiconductor device comprises a circuit portion, wells, and dummy wells. A circuit portion is formed on an upper surface of a semiconductor substrate of a first conductivity type. The wells are of a second conductivity type different from the first conductivity type. Each of wells is formed in the semiconductor substrate on an upper surface side, constitutes the circuit portion, and functions as an element. The dummy wells are of the second conductivity type. Each of the dummy wells is formed in the semiconductor substrate on the upper surface side, does not constitute the circuit portion, and does not function as an element.

In backside FIB processing, a correction point is processed while observing an FIB image of an interconnection or a transistor by irradiating the semiconductor substrate with an ion beam from the lower surface side. At this time, since the semiconductor substrate has no characteristic pattern on the back side, the position cannot be specified in the FIB image. To specify the approximate position of the target interconnection, an optical image is generally used together with the FIB image.

In the backside FIB processing, a trench is formed for the correction point from the lower surface side of the semiconductor substrate to detect the n-well in the semiconductor substrate on the upper surface side. After the point is specified using the n-well pattern, alignment with CAD (Computer Aided Design) data is done, thereby specifying the final interconnection correction point and pad formation point.

In some cases, however, no n-well exists near the interconnection correction point. The range of the trench formable by one process is limited. For this reason, if no n-well exists near the correction point, the n-well is not detected even when the trench is formed. In this case, trench formation needs to be performed twice or more. That is, after trench formation, point specification, and CAD data alignment are done in another place with the n-well, another trench adjacent to the trench needs to be formed again.

That is, if the n-well is not detected, specifying the place of the correction point becomes difficult. In addition, trench formation is very time-consuming, and performing this step twice or more greatly prolongs the process time. Furthermore, since the distance from the place where the n-well has been specified to the correction point increases, misalignment with the CAD data readily occurs. As a result, the process accuracy lowers.

The embodiments will now be described with reference to the accompanying drawings. The same reference numerals denote the same parts throughout the drawings.

### [FIB Processing Apparatus]

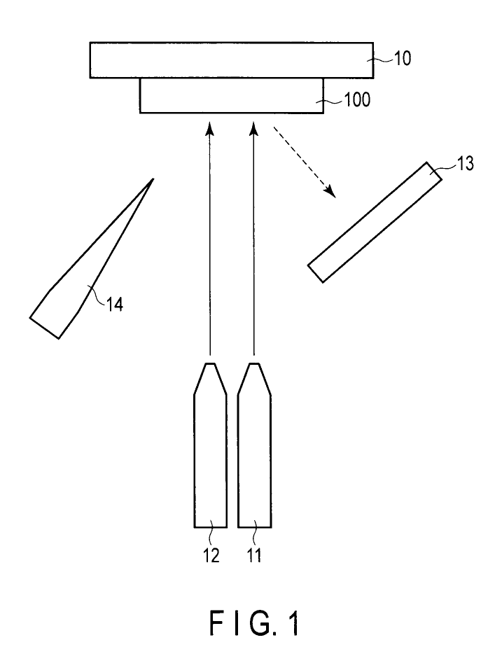

An FIB processing apparatus for performing FIB processing for a semiconductor substrate according to each embodiment will be described below with reference to FIG. 1.

FIG. 1 is a schematic view of the FIB processing apparatus to be used for a semiconductor device according to each embodiment.

As shown in FIG. 1, the FIB processing apparatus comprises a sample table 10, an ion beam gun 11, an IR (infrared) camera 12, a detector 13, and a process gas nozzle 14.

A semiconductor chip 100 as the FIB processing target is set and fixed on the sample table 10.

The ion beam gun 11 irradiates the semiconductor chip 100 with an FIB of Ga ions or the like. This FIB irradiation makes it possible to process (etch) the semiconductor chip 100 and observe the FIB image. The FIB intensity can appropriately be changed. The higher the intensity is, the higher the process speed is. The lower the intensity is, the lower the process speed is. Deflecting the FIB allows it to scan on the semiconductor chip 100. The scanning speed and scanning width at this time can appropriately be changed. Note that it is also possible to scan the FIB on the semiconductor chip 100 by moving the sample table 10.

The IR camera 12 acquires the optical image of the semiconductor chip 100. The IR camera 12 is provided to be coaxial with the ion beam gun 11. The IR camera 12 and the ion beam gun 11 are used parallelly.

The detector 13 detects secondary electrons generated by the FIB that has irradiated the semiconductor chip 100, thereby acquiring the FIB image. The FIB image acquired by the detector 13 and the optical image acquired by the IR camera 12 are displayed on a monitor (not shown). The FIB image and the optical image can always be observed during the process of the semiconductor chip 100.

The process gas nozzle 14 sends a blast of an appropriate process gas to the semiconductor chip 100. The process gas decomposes by FIB irradiation to etch the semiconductor chip 100 or deposit a conductive material or an insulating material on the semiconductor chip 100. This allows to reconnect the interconnections and the like of the semiconductor chip 100.

Note that the FIB processing apparatus is provided in a vacuum chamber (not shown), and the above-described operation is performed in the vacuum.

The circuit portion formed on the upper surface side of the semiconductor chip (semiconductor substrate) is FIB-processed from the lower surface side using the FIB processing apparatus, thereby performing pad formation or reconnection of interconnections for signal acquisition.

### [Backside FIB Processing]

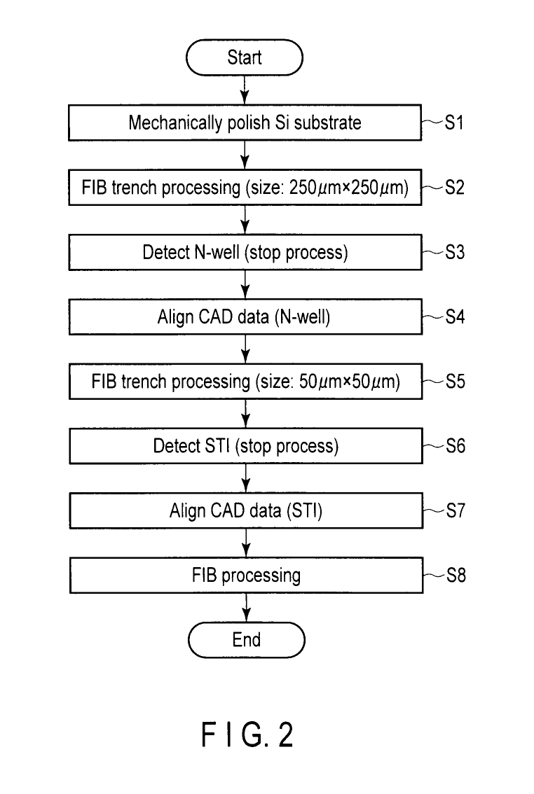

Backside FIB processing to be performed for the semiconductor device according to each embodiment will be described below with reference to FIGS. 2 to 5.

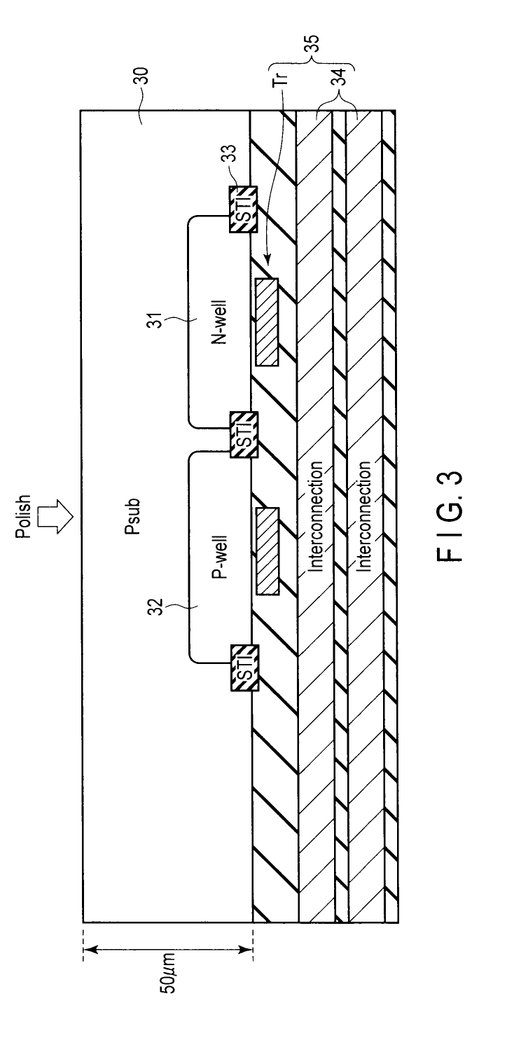

FIG. 2 is a flowchart of backside FIB processing to be performed for the semiconductor device according to each embodiment. FIGS. 3 to 5 are sectional views of the semiconductor device during midway processes of the backside FIB processing. Note that in FIGS. 3 to 5, the lower side of the drawings is defined as the upper surface side, and the upper side is defined as the lower surface side.

As shown in FIG. 2, first, in step S1, the semiconductor substrate is mechanically polished. More specifically, as shown in FIG. 3, a semiconductor substrate 30 having, on its upper surface, a circuit portion 35 including transistors Tr and interconnections 34 is polished from the lower surface side by a grinder. With this polishing, the film thickness of the semiconductor substrate 30 decreases to about 50 μm. Note that the detailed polishing method is known, and various polishing methods are usable in this embodiment. After that, the polished semiconductor substrate 30 is set in the FIB processing apparatus.

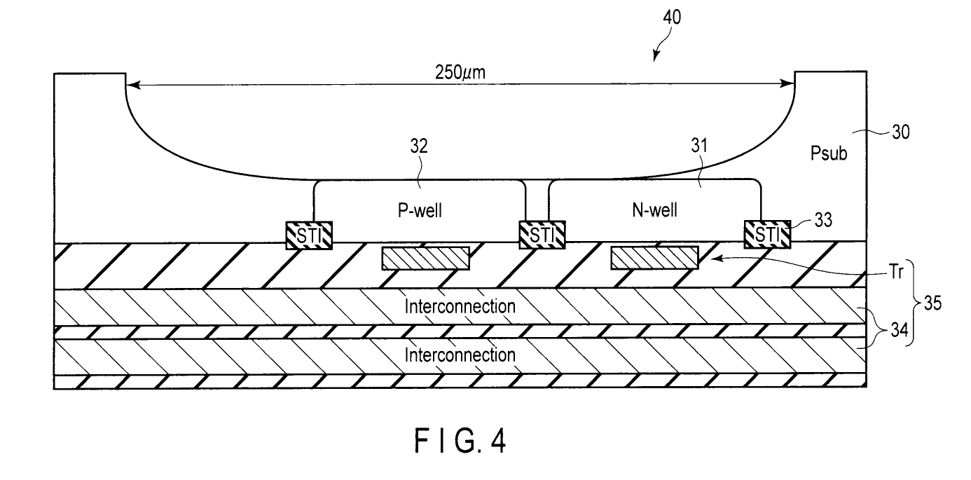

In step S2, FIB trench processing is performed in a wide range. More specifically, as shown in FIG. 4, a trench 40 is formed in, for example, a 250×250 μm region from the lower surface side of the semiconductor substrate 30. The trench 40 is formed by irradiating the semiconductor substrate 30 with an FIB from the FIB processing apparatus from the lower surface side while scanning the FIB. The trench formation is performed using a strong FIB at a high scanning speed because it is done in the wide range. A correction point (not shown) of the circuit portion 35 is included in the 250×250 μm region where the trench 40 is formed. In other words, the trench 40 is formed immediately under the correction point (on the upper side of the drawing). Note that the 250×250 μm region is an example, and the trench formation is preferably performed in the maximum width of FIB scanning of the FIB processing apparatus.

In step S3, an n-well 31 is detected. More specifically, as shown in FIG. 4, when forming the trench 40, the n-well 31 formed in the semiconductor substrate 30 on the upper surface side is detected. When the n-well 31 is exposed, formation of the trench 40 is stopped. The n-well 31 is detected by observing the FIB image. At this time, the n-well 31 is detected by observing a change in the color or the like of the FIB image. Note that formation of the trench 40 may be stopped upon detecting a p-well 32. However, if the semiconductor substrate 30 is of the p type, the n-well 31 can be detected more easily than the p-well 32. Hence, the n-well 31 is preferably detected.

In step S4, alignment with CAD data (design data) is performed. More specifically, point specification is done using the n-well 31 detected in step S3, and the n-well 31 observed as the FIB image is aligned with the CAD data. At this time, the alignment with the CAD data is done based on, for example, the corners of the n-well 31. This allows to perform alignment at an accuracy of about 0.5 μm.

Next, a narrower process range is set, and alignment is performed again.

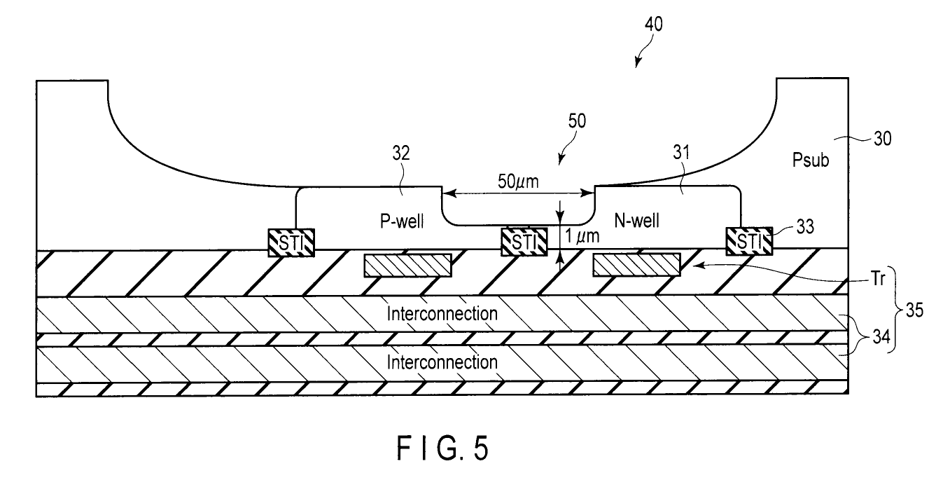

First, in step S5, FIB trench formation is performed in the narrower range. More specifically, as shown in FIG. 5, a trench 50 is formed in, for example, a 50×50 μm region at a part of the bottom surface of the trench 40 on the lower surface side of the semiconductor substrate 30. The trench 50 is formed by irradiating the semiconductor substrate 30 with an FIB from the FIB processing apparatus from the lower surface side while scanning the FIB. In addition, the FIB is weakened, and the scanning speed is lowered, thereby uniforming the depth of the trench 50. A correction point (not shown) of the circuit portion 35 is included in the 50×50 μm region where the trench 50 is formed. In other words, the trench 50 is formed immediately under the correction point (on the upper side of the drawing). Note that the 50×50 μm region is an example, and the trench formation is preferably performed in a narrow range capable of including the correction point.

In step S6, an STI 33 is detected. More specifically, as shown in FIG. 5, when forming the trench 50, the STI 33 formed on the upper surface of the semiconductor substrate 30 is detected. When the STI 33 is exposed, formation of the trench 50 is stopped. The STI 33 is detected by observing the FIB image. At this time, the STI 33 is detected by observing a change in the color or the like of the FIB image, as in detection of the n-well 31.

In step S7, alignment with CAD data is performed. More specifically, point specification is done using the STI 33 detected in step S6, and the STI 33 observed as the FIB image is aligned with the CAD data. At this time, the alignment with the CAD data is done based on, for example, the corners of the STI 33. Since the pattern of the STI 33 is smaller than that of the n-well 31, the alignment can be done at an accuracy higher than that when using the n-well 31. With the above-described process, the trenches 40 and 50 are formed up to the depth of the STI 33, and the depth to the target interconnection decreases to 1 μm or less so that the correction point can be FIB-processed.

In step S8, FIB processing is performed for the correction point such as an interconnection. More specifically, a connection hole (not shown) is formed at the aligned correction point to expose the correction point. After that, FIB processing is performed for the exposed correction point to do pad formation or reconnection of interconnections for signal acquisition. The backside FIB processing is performed in this way.

### FIRST EMBODIMENT

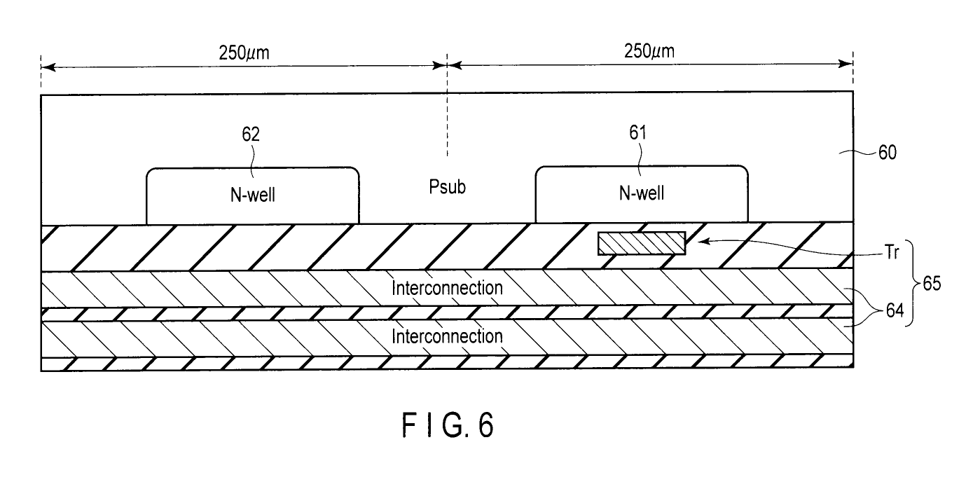

A semiconductor device according to the first embodiment will be described below with reference to FIGS. 6, 7, and 8.

### [Structure]

FIG. 6 is a sectional view showing the semiconductor device according to the first embodiment. Note that in FIG. 6, the lower side of the drawing is defined as the upper surface side, and the upper side is defined as the lower surface side.

As shown in FIG. 6, the semiconductor device according to the first embodiment includes a circuit portion 65 formed on the upper surface of a p-type semiconductor substrate 60, and a first n-well (well) 61 and a second n-well (dummy well) 62 which are formed in the semiconductor substrate 60.

The circuit portion 65 includes a transistor Tr formed on the upper surface of the semiconductor substrate 60, and interconnections 64 formed on the transistor Tr. Note that although two layers of interconnections 64 are formed in FIG. 6, the embodiment is not limited to this.

The first n-well 61 and the second n-well 62 are formed in the semiconductor substrate 60 on the upper surface side. The first n-well 61 is formed in a region where the element is formed, and the second n-well 62 is formed in another region. That is, the first n-well 61 forms the transistor Tr and the like and functions as the element in the circuit portion 65 while the second n-well 62 does not form the transistor Tr and the like, and does not function as the element in the circuit portion 65. Note that to avoid the floating state of the second n-well 62, it is preferable to form an n⁺-type diffusion layer in the second n-well 62, connect a contact (not shown) to the diffusion layer, and apply a voltage VDD to the second n-well 62.

At least one of the first n-well 61 and the second n-well 62 is formed in a predetermined region (for example, a 250×250 μm region) in the semiconductor device according to the first embodiment, although details will be described later.

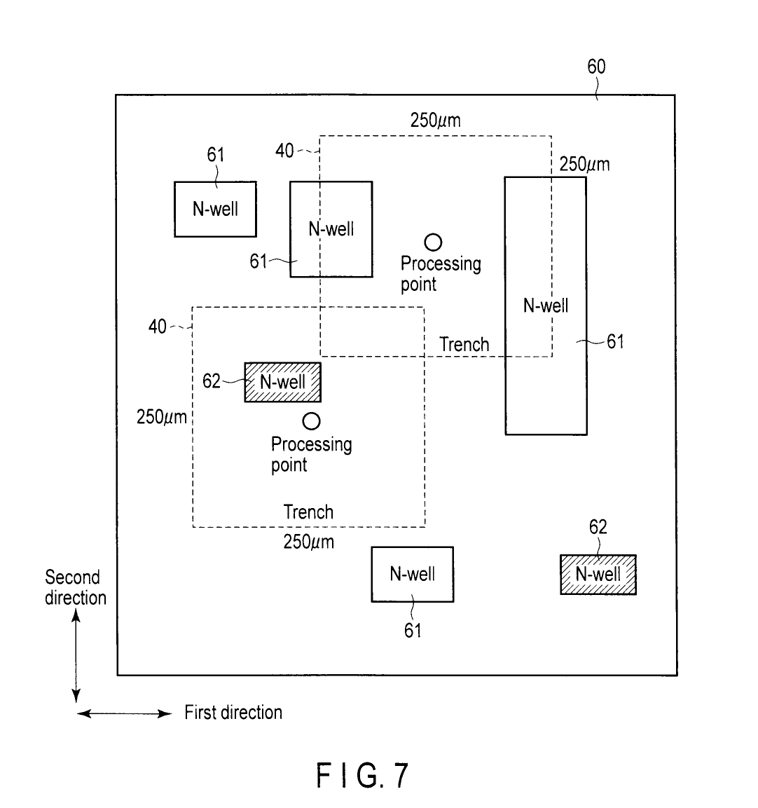

FIG. 7 is a plan view showing an example of the semiconductor device according to the first embodiment. Note that FIG. 7 mainly illustrates the n-well arrangement, and the circuit portion is omitted.

As shown in FIG. 7, the semiconductor device according to the first embodiment comprises a plurality of first n-wells 61 and a plurality of second n-wells 62 on the semiconductor substrate 60 spreading in the plane along the first direction and the second direction perpendicular to the first direction. As described above, to correct a part of the circuit portion 65 from the lower surface side of the semiconductor substrate 60 using FIB processing, a trench 40 is formed immediately under the correction point of the circuit portion 65 in the semiconductor substrate 60 on the lower surface side, thereby detecting an n-well. The region where the trench 40 is formed is, for example, a 250×250 μm region (250 μm square region) corresponding to the maximum FIB scanning width of the FIB processing apparatus.

In the first embodiment, at least one of the plurality of first n-wells 61 and the plurality of second n-wells 62 exists in an arbitrary 250×250 μm region in the plane. In other words, a second n-well 62 is formed in a 250×250 μm region where none of the plurality of first n-wells 61 that constitute the transistor Tr exists. In addition, a second n-well 62 is formed in a region where the existence density of the plurality of first n-wells 61 is equal to or lower than a predetermined density (for example, one first n-well 61 in a 250×250 μm region) in the plane. Furthermore, if the distance between two adjacent first n-wells 61 is equal to or larger than a predetermined distance (for example, 250 μm), a second n-well 62 is formed in the region between them. That is, when an arbitrary 250 μm square region is selected in the plane, at least one of the plurality of first n-wells 61 and the plurality of second n-wells 62 can be detected.

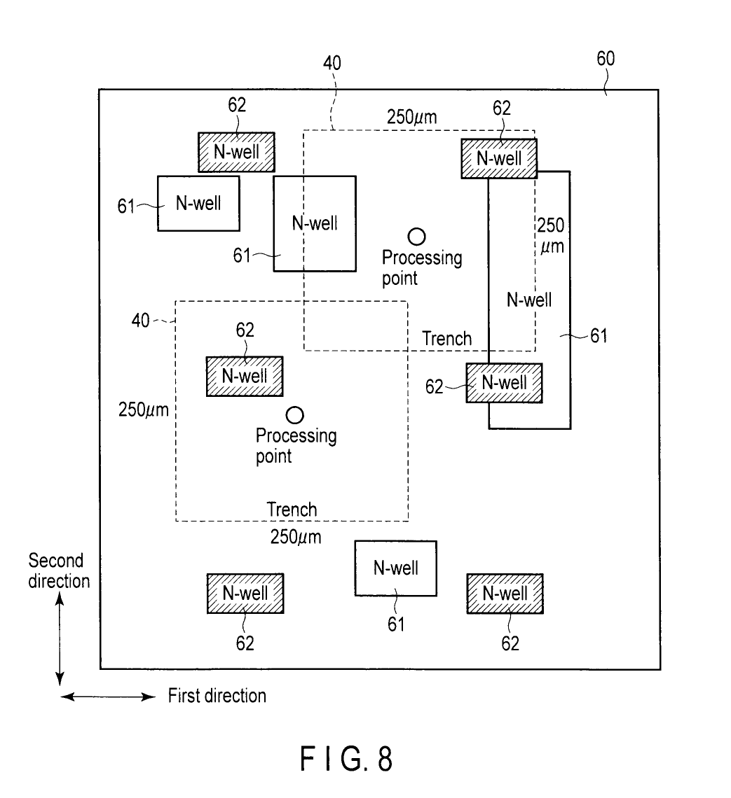

FIG. 8 is a plan view showing another example of the semiconductor device according to the first embodiment. Note that FIG. 8 mainly illustrates the n-well arrangement, and the circuit portion is omitted.

As shown in FIG. 8, in the other example, each of the plurality of second n-wells 62 are formed at a predetermined interval (for example, 250 μm) in the plane (in the first direction and the second direction). In other words, the plurality of second n-wells 62 are formed in a matrix in the first direction and the second direction. At this time, the second n-wells 62 and the first n-wells 61 may partially overlap.

### [Effects]

According to the first embodiment, the second n-well 62 that does not constitute the circuit portion 65 and is used for point specification (marking) in backside FIB processing is formed in the semiconductor substrate 60 independently of the first n-well 61 that constitutes the circuit portion 65 (the transistor Tr and the like). This enables to arrange one of the first n-well 61 and the second n-well 62 in the region where the trench 40 is formed in the backside FIB processing. It is therefore possible to easily detect the n-well and easily specify the point in the backside FIB processing.

Additionally, one of the first n-well 61 and the second n-well 62 can be detected by forming the trench 40 once. For this reason, the trench 40 need not be formed twice or more, and the increase in the backside FIB processing time can be suppressed.

Furthermore, a plurality of first n-wells 61 or a plurality of second n-wells 62 can also be formed in the formation region of the trench 40. This makes it possible to increase the number of wells serving as marks, facilitate point specification in the backside FIB processing, and improve the accuracy of alignment with CAD data.

### SECOND EMBODIMENT

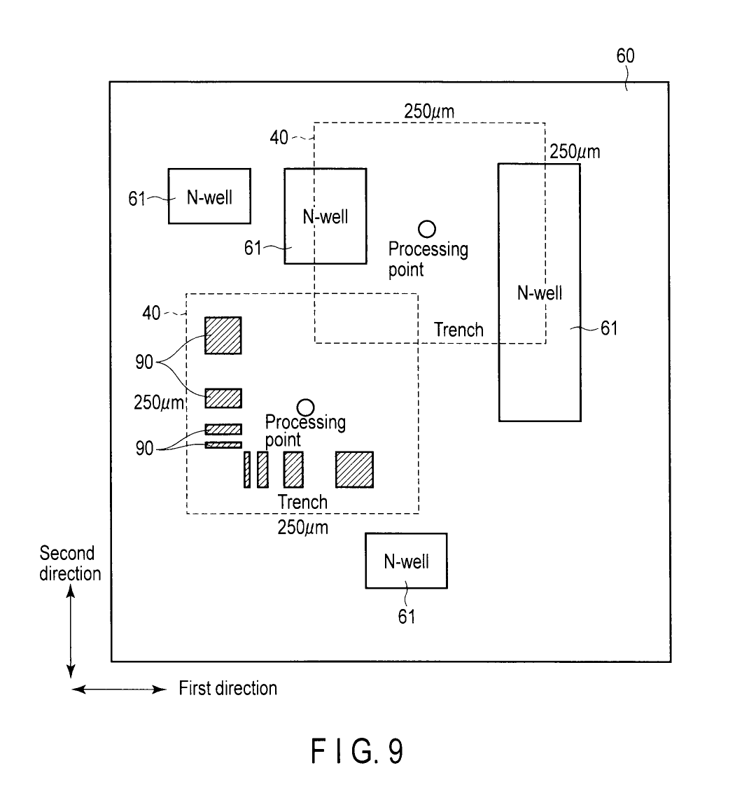

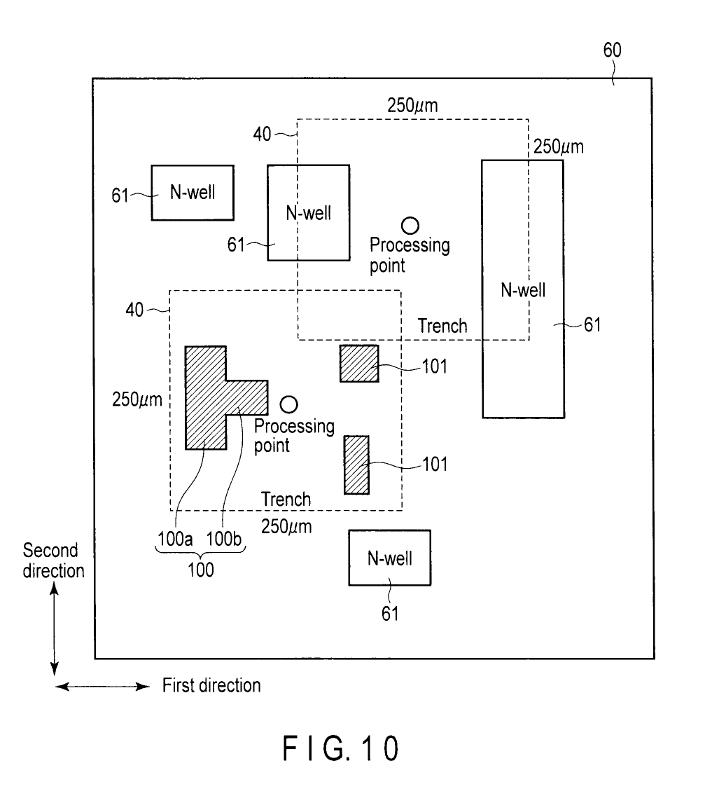

A semiconductor device according to the second embodiment will be described below with reference to FIGS. 9 and 10. Note that in the second embodiment, a description of the same points as in the first embodiment will be omitted, and different points will be explained.

### [Structure]

FIG. 9 is a plan view showing an example of the semiconductor device according to the second embodiment.

As shown in FIG. 9, the semiconductor device of the second embodiment is different from that of the first embodiment in that a characteristic n-well pattern is formed.

More specifically, in the semiconductor device according to the second embodiment, second n-wells (dummy wells) 90 whose shapes are different from those of first n-wells 61 are formed. In addition, a predetermined number of second n-wells 90 having different shapes are formed in a 250×250 μm region, as illustrated. That is, a predetermined number of second n-wells 90 having different shapes are densely formed in a relatively narrow range. In this example, a plurality of rectangular (square) second n-wells 90 are formed in a 250×250 μm region so as to gradually increase the width along the first direction and the second direction.

FIG. 10 is a plan view showing another example of the semiconductor device according to the second embodiment.

As shown in FIG. 10, in the other example, a second n-well (dummy well) 100 has steps. More specifically, the second n-well 100 includes a first portion 100a and a second portion 100b narrower than the first portion 100a. In other words, the second n-well has such a shape that the second portion 100b projects from the first portion 100a. That is, the second n-well 100 having a step shape in the plane and rectangular (square) second n-wells 101 are formed in a 250×250 μm region.

Note that the second n-well of the second embodiment need not always have the shapes and patterns shown in FIGS. 9 and 10. For example, in place of a predetermined number of second n-wells 90 having different widths shown in FIG. 9, a predetermined number of second n-wells 90 having different areas or side lengths may be formed. The second n-wells 90 need not be rectangular or square and may have a constricted shape. A predetermined number of second n-wells 100 having a step shape shown in FIG. 10 may be formed in the 250×250 μm region. Alternatively, a predetermined number of second n-wells having various shapes such as rectangular, square, constricted, and step shapes may be combined and formed in the 250×250 μm region. Instead of a predetermined number of characteristic second n-wells, at least one characteristic second n-well may be formed in the 250×250 μm region.

### [Effects]

According to the second embodiment, the same effects as in the first embodiment can be obtained.

Additionally, in the second embodiment, at least one of the characteristic second n-wells 90, 100, and 101 having shapes different from those of the first n-wells 61 is formed in the formation region (for example, a 250×250 μm region) of a trench 40. This makes it possible to use the second n-wells 90, 100, and 101 having characteristic shapes as marks, facilitate point specification in the backside FIB processing, and improve the accuracy of alignment with CAD data.

### THIRD EMBODIMENT

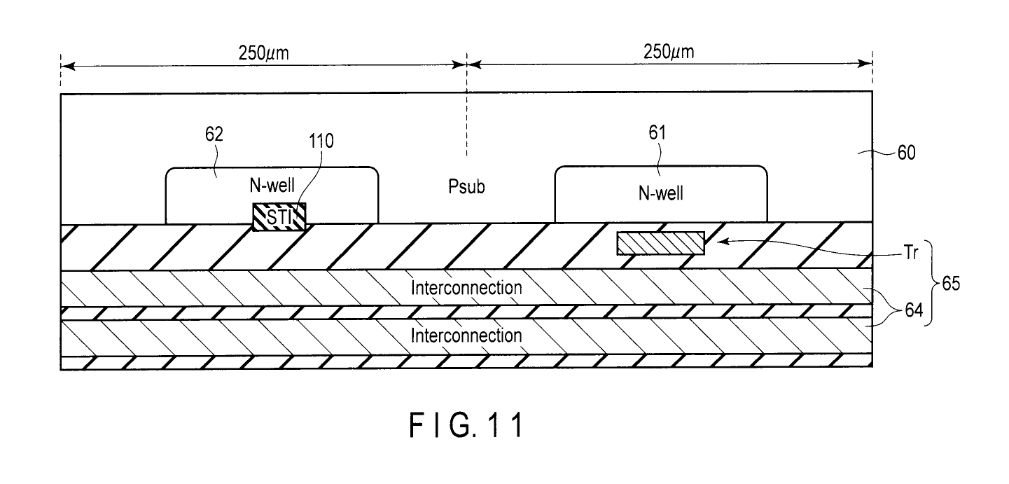

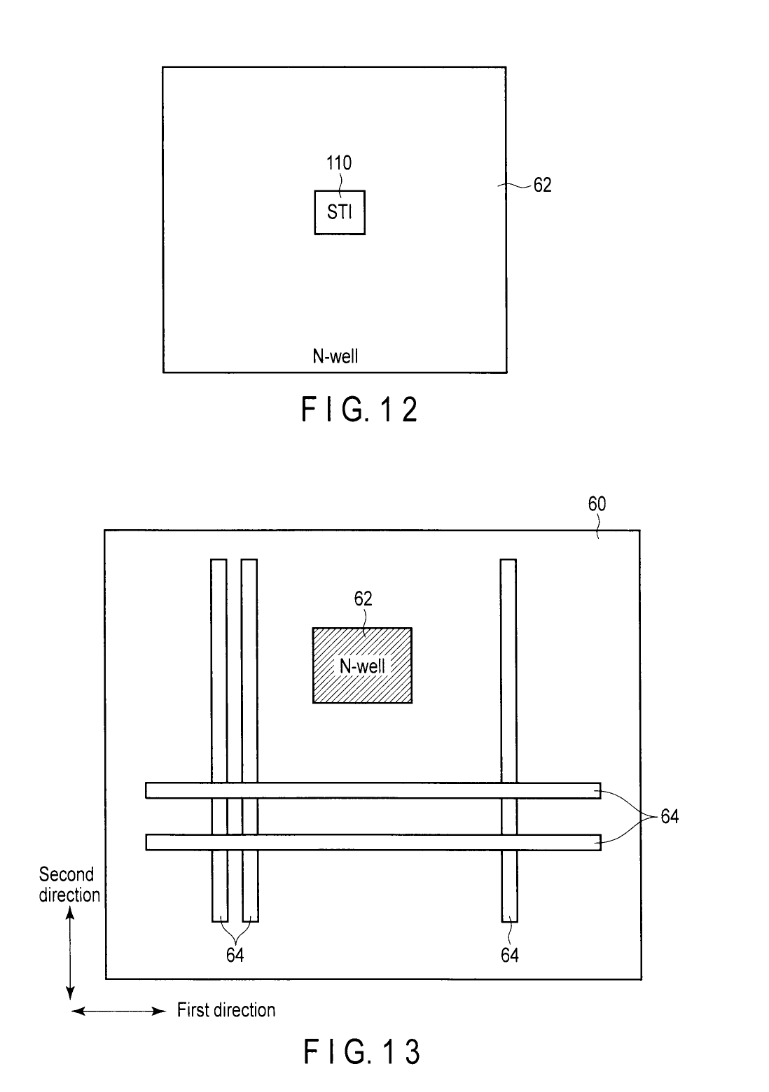

A semiconductor device according to the third embodiment will be described below with reference to FIGS. 11 and 12. Note that in the third embodiment, a description of the same points as in the first embodiment will be omitted, and different points will be explained.

### [Structure]

FIG. 11 is a sectional view showing the semiconductor device according to the third embodiment. FIG. 12 is a plan view showing the second n-well of the semiconductor device according to the third embodiment.

As shown in FIGS. 11 and 12, the semiconductor device of the third embodiment is different from that of the first embodiment in that an STI is formed in the region where the second n-well is formed.

As described above, when correcting a part of a circuit portion 65 from the lower surface side of a semiconductor substrate 60 by FIB processing, a trench is formed immediately under the correction point of the circuit portion 65 in the semiconductor substrate 60 on the lower surface side to detect the n-well and the STI.

In the semiconductor device of the third embodiment, an STI (dummy STI) 110 formed from, for example, a silicon oxide film is formed in the region where a second n-well 62 is formed in the plane on the upper surface side of the semiconductor substrate 60. As shown in FIG. 11, the STI 110 is formed at a position shallower than the second n-well 62 in the semiconductor substrate 60. In addition, as shown in FIG. 12, the pattern of the STI 110 is smaller than that of the second n-well 62. More specifically, the second n-well 62 has a size of about several μm to several ten μm square, where as the STI 110 has a size of about 1 μm square.

Note that in FIG. 12, only one STI 110 is formed in the region where the second n-well 62 is formed. However, a plurality of STIs may be formed.

### [Effects]

According to the third embodiment, the same effects as in the first embodiment can be obtained.

Additionally, in the third embodiment, the STI having a pattern smaller than that of the second n-well 62 is formed in the region where the second n-well 62 is formed. This makes it possible to use the STI with the smaller pattern as a mark and improve the accuracy of point specification and alignment with CAD data in the backside FIB processing.

### FOURTH EMBODIMENT

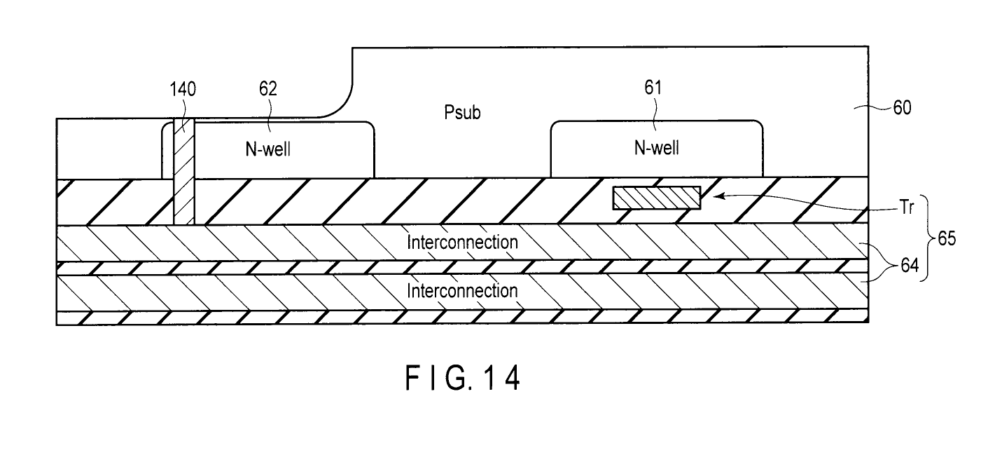

A semiconductor device according to the fourth embodiment will be described below with reference to FIGS. 13 and 14. Note that in the fourth embodiment, a description of the same points as in the first embodiment will be omitted, and different points will be explained.

### [Structure]

FIG. 13 is a plan view showing the semiconductor device according to the fourth embodiment. Note that FIG. 13 mainly illustrates the second n-well and the interconnections, and the first n-well is omitted.

As shown in FIG. 13, the semiconductor device of the fourth embodiment is different from that of the first embodiment in that the second n-well is formed in a region where no interconnections exist.

More specifically, in the semiconductor device according to the fourth embodiment, a second n-well 62 is formed in a semiconductor substrate 60 on the upper surface side in a region where no interconnections 64 exist above. In other words, the second n-well 62 is formed in the region between the plurality of interconnections 64 running in the plane. That is, the second n-well 62 and the interconnections 64 are arranged not to overlap, as illustrated. This aims at preventing shorts between the second n-well 62 and the interconnections 64 when correcting the interconnections 64 by backside FIB processing, as will be described later. The second n-well 62 is formed before formation of the interconnections 64. A region where no interconnections 64 are formed later is selected based on design data, and the second n-well 62 is formed in that region.

### [Effects]

According to the fourth embodiment, the same effects as in the first embodiment can be obtained.

The following problem arises when correcting a part of the interconnections 64 by backside FIB processing. As shown in FIG. 14, when correcting a part of the interconnection 64 arranged above the second n-well 62, a connection hole is formed in the second n-well 62 to expose the correction point of the interconnection 64. After that, a conductive material 140 fills the connection hole to correct (reconnect) the interconnection 64. That is, the second n-well 62 is filled with the conductive material 140. A voltage VDD is applied to the second n-well 62 via a contact (not shown). For this reason, when the conductive material 140 is formed in the second n-well 62, a short occurs between the second n-well 62 and the conductive material 140. In addition, the correction point of the interconnection 64 is checked and corrected after all components are completed (the second n-well 62 and the interconnections 64 are completed). It is therefore difficult to process the interconnection 64 while avoiding the second n-well 62.

In the fourth embodiment, however, the second n-well 62 is formed based on the design data in the region where no interconnections 64 exist. For this reason, when correcting a part of the interconnection 64 by the backside FIB processing, neither the connection hole nor the conductive material 140 is formed in the second n-well 62. This allows to avoid the above-described problem and easily perform the backside FIB processing.

Note that the dummy well and the dummy STI which do not function as elements in the first to fourth embodiments can be formed in the same process and method as those of the well and STI functioning as elements.

The structures of two or all of the second to fourth embodiments may be combined with each other.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a circuit portion formed on an upper surface of a semiconductor substrate of a first conductivity type;
wells of a second conductivity type different from the first conductivity type, each of which is formed in the semiconductor substrate on an upper surface side, constitutes the circuit portion, and functions as an element; and
dummy wells of the second conductivity type, each of which is formed in the semiconductor substrate on the upper surface side, does not constitute the circuit portion, and does not function as an element.

2. The device of claim 1, wherein
when correcting a part of the circuit portion from a lower surface side of the semiconductor substrate by FIB processing, an FIB trench is formed under the part in the semiconductor substrate on the lower surface side upon the FIB processing, and
at least one of the wells and the dummy wells exists in a region where the FIB trench is formed.

3. The device of claim 1, wherein the dummy wells exist in a region where an existence density of the wells is not more than a first density.

4. The device of claim 1, wherein if a distance between two adjacent wells out of the wells is not less than a first distance, the dummy wells exist in a region between the two wells.

5. The device of claim 1, wherein the dummy wells exist at a first interval.

6. The device of claim 5, wherein the dummy wells are formed in a matrix.

7. The device of claim 1, wherein at least one of the wells and the dummy wells exists in an arbitrary region having a first size.

8. The device of claim 1, wherein the dummy wells are used for point specification when correcting a part of the circuit portion from a lower surface side of the semiconductor substrate by FIB processing.

9. The device of claim 1, wherein some of the dummy wells overlap some of the wells.

10. The device of claim 1, wherein the dummy wells have shapes different from those of the wells.

11. The device of claim 10, wherein at least one of the dummy wells has a step shape.

12. The device of claim 10, wherein the dummy wells have shapes different from each other.

13. The device of claim 10, wherein
when correcting a part of the circuit portion from a lower surface side of the semiconductor substrate by FIB processing, an FIB trench is formed under the part in the semiconductor substrate on the lower surface side upon the FIB processing, and
a predetermined number of dummy wells out of the dummy wells exist in a region where the FIB trench is formed and have shapes different from each other.

14. The device of claim 1, wherein an STI is formed in the semiconductor substrate on the upper surface side in a region where the dummy wells are formed.

15. The device of claim 14, wherein the STI includes a silicon oxide film.

16. The device of claim 14, wherein the STI has a pattern smaller than that of the dummy wells and is formed at a position shallower than the dummy wells in the semiconductor substrate.

17. The device of claim 1, wherein
the circuit portion includes interconnections running, and
the dummy wells exist in a region between the interconnections.

18. The device of claim 1, wherein the first conductivity type is a p type, and the second conductivity type is an n type.

19. The device of claim 18, wherein each of the dummy wells includes an n⁺-type diffusion layer, and a voltage is applied to the diffusion layer.

20. The device of claim 1, wherein each of the dummy wells has a size of about several μm to several ten μm square.
